(19) United States
(12) Patent Application Publication
(10) Pub. No.: US 2026/0094649 A1
(43) Pub. Date: Apr. 2, 2026

(54) PROGRAMMABLE READ-ONLY MEMORY (PROM)

(71) Applicants: Arindrajit Ghosh, College Station, TX (US); Rohit Hooda, Austin, TX (US)

(72) Inventors: Arindrajit Ghosh, College Station, TX (US); Rohit Hooda, Austin, TX (US)

(21) Appl. No.: 18/898,919

(22) Filed: Sep. 27, 2024

(51) Int. Cl. G11C 16/26; G11C 5/06; G11C 16/08; G11C 16/32

(52) U.S. Cl. CPC G11C 16/26; G11C 5/063; G11C 16/08; G11C 16/32

(57) ABSTRACT

An apparatus includes an N-type bit-cell bundle with a first N-type bit-cell array, a first merge circuit, and a second N-type bit-cell array coupled to the first N-type bit-cell array via the first merge circuit. The apparatus includes a P-type bit-cell bundle coupled in a horizontal direction to the N-type bit-cell bundle via a spacer area. The P-type bit-cell bundle includes a first P-type bit-cell array, a second merge circuit, and a second P-type bit-cell array. The second P-type bit-cell array is coupled to the first P-type bit-cell array via the second merge circuit.

### BACKGROUND

Maintaining the appropriate diffusion density is a critical aspect of embedded ROM design. Since the ROM bitcell primarily consists of NMOS transistors, it is easy to exceed the maximum allowable density for N-type diffusion if not properly managed within the specified density limits. Conversely, the minimum density parameters may not be met for P-type diffusion if there are not enough dummy P-type diffusions to compensate for a lack of active P-type devices in the ROM. Therefore, achieving a careful balance between N and P-type diffusions is essential, ensuring adherence to both the maximum N-type and minimum P-type diffusion density requirements.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings listed below.

FIG. 1 is a block diagram of exposed N-type diffusion density calculations, in accordance with some embodiments.

FIG. 2 illustrates requirement windows for maximum N/P diffusion density calculations, in accordance with some embodiments.

FIG. 3 is a block diagram of a horizontal bit-slice placement of dummy P-diffusion in node N ROM solution for node N+1 ROM, in accordance with some embodiments.

FIG. 4 is a block diagram of horizontal bit-slice placement of dummy P-diffusion for array slice with node N+1 ROM, in accordance with some embodiments.

FIG. 5 is a block diagram of the vertical placement of dummy P-diffusion for node N+1 ROM along with horizontal placement, in accordance with some embodiments.

FIG. 6A and FIG. 6B are block diagrams of the functionality of both N and P-type PROM bit-cells, in accordance with some embodiments.

FIG. 7 is a block diagram of an array floor plan before and after the application of the disclosed techniques with 1 poly ROM bit-cells in Node N, in accordance with some embodiments.

FIG. 8 is a block diagram of an array floor plan before and after the application of the disclosed techniques with 1.5 poly ROM bit-cells in Node N+1, in accordance with some embodiments.

FIG. 9 is a block diagram of a circuit solution to support both N and P-type bit-cells in a horizontal direction of a bit slice, in accordance with some embodiments.

FIG. 10 illustrates read functionality changes among two bundles, in accordance with some embodiments.

FIG. 11 is an example ROM floor plan, in accordance with some embodiments.

FIG. 12 is an example multibit ROM floor plan based on the disclosed techniques, in accordance with some embodiments.

FIG. 13 is an example circuit behavior of an N-type bit slice, in accordance with some embodiments.

FIG. 14 is an example circuit behavior of a P-type bit slice, in accordance with some embodiments.

FIG. 15, FIG. 16, and FIG. 17 illustrate read functionality changes among two slices for a multi-bit ROM, in accordance with some aspects.

FIG. 18 is a flow diagram of an example method for manufacturing a memory bit-cell array, in accordance with some embodiments.

FIG. 19 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

As used herein, the term “IO” indicates input/output. As used herein, the term “R-C” indicates resistance and capacitance. As used herein, the term “Rx” indicates receiver (or receive). As used herein, the term “Tx” indicates transmitter (or transmit). As used herein, the term “TRX” indicates transceiver. As used herein, the term “UCIe” indicates Universal Chiplet Interconnect Express. As used herein, the term “Vref” indicates reference voltage. As used herein, the term “Vin” indicates input voltage. As used herein, the terms “serially coupled,” “serially connected,” and “connected in series” are synonymous to each other and indicate a serial connection between two or more components/circuits where the serial connection can be based on a direct or indirect electrical connection between the two or more components/circuits. As used herein, the terms “parallel coupled,” “parallel connected,” and “connected in parallel” are synonymous to each other and indicate a parallel connection between two or more components/circuits where the parallel connection can be based on a direct or indirect electrical connection between the two or more components/circuits.

The disclosed techniques include configurations for memory cells including a combination of P and N-type PROM bit-cells to remove diffusion density limitations for ultra-high density embedded ROM. The disclosed techniques also include diffusion density resist multi-bit PROM for ultra-high-density embedded ROM.

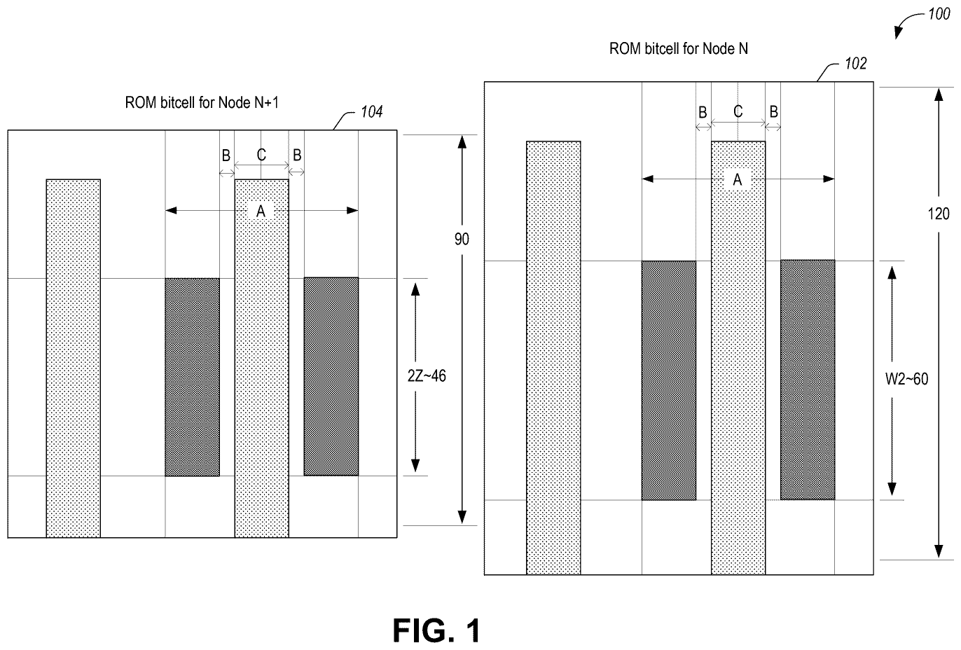

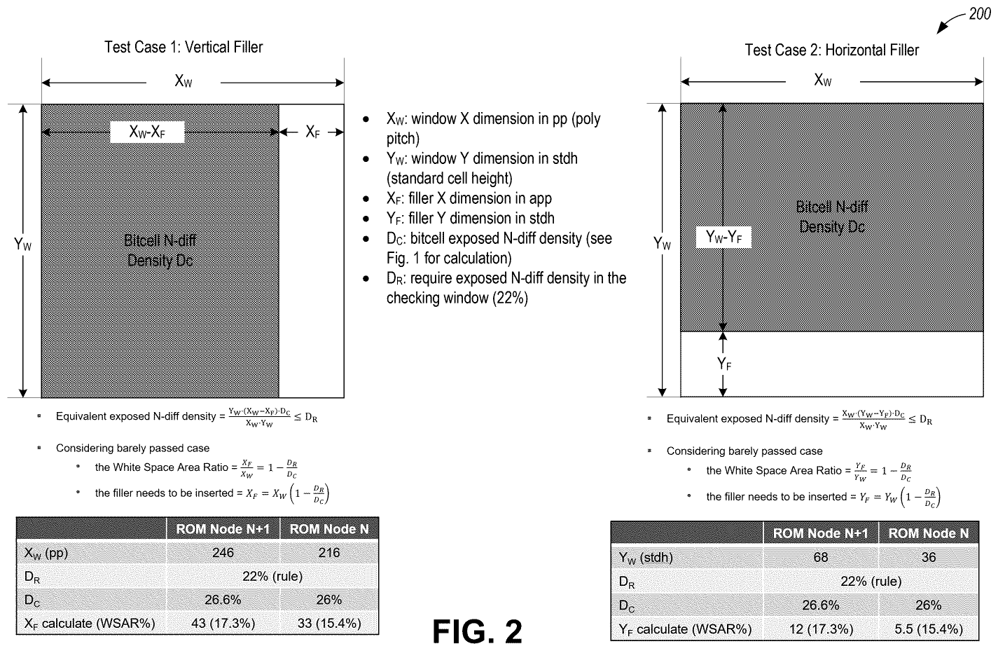

Diffusion density requirements can change from one technology node to another. FIG. 1 is a block diagram 100 of exposed N-type diffusion density calculations, in accordance with some embodiments. More specifically, FIG. 1 shows the exposed N-diffusion calculation of a ROM bitcell in two consecutive process nodes (e.g., N node 102 and N+1 node 104). Data shows that when moving from node N to N+1, the density requirement per bit-cell is increasing (e.g., in the order of 26% to 26.6%). Simultaneously, the window size also changes when moving from node N to N+1 but requires exposed N/P-diffusion density in checking the window that is fixed at 22% and 4% for max and min density, respectively.

FIG. 2 illustrates a diagram 200 of requirement windows for maximum N/P diffusion density calculations, in accordance with some embodiments. More specifically, FIG. 2 illustrates window-wise array density clean-up of two consecutive node data associated with two test cases. Test Case-1 (TC1): consideration of vertical filler and Test Case-2 (TC2): consideration of horizontal filler. Both test cases (TC1 and TC2) show to get a maximum N diffusion density, a clean XF and YF amount of white space is needed, or in that space, it needs to be filled with dummy P diffusion to get clean on minimum P diffusion density. The following numbers (XF and YF) are going to be bigger in design because of the periphery logic and criticality of DRCDs in advanced nodes.

It is clear from the above data point reflected in FIG. 2 that diffusion density is an extra area overhead for ROM design. Multiple layout efforts may be necessary for optimum floor planning to achieve the most efficient area. Still, there is going to be an extra area of 10% to 18% overheads to satisfy Max N and Min P diffusion density rules, accounting for free white space or through dummy P diffusions. Effectively, those can be redundant in terms of design logic and active circuit functionality point of view, but still, process design rules can be improved based on the disclosed techniques.

Historically, ROM usages are mainly for Basic Input/Output Systems (BIOS) and for data applications where data is always going to be static. For futuristic AI applications, a cost-effective, dedicated solution is needed for Artificial intelligence interface tasks. Research is going on a new technology for real time generative AI interface. It can reach up to 150 times better performance and get these 3000 better energies per token for large language models (LLMs) that are trained on large sets of data to recognize, summarize, translate, predict, and generate content using natural language compared to H100 (GPU chip manufactured by Nvidia). To achieve this, there can be used multiple embedded ROMS on a large die (>400 mm²), which is going to be >50% of the die area.

For this type of AI product, performance may not be as important as throughput and efficiency (both energy and area). Hence it is essential to rethink about high density ROM by eliminating extra overheads due to diffusion density. The disclosed techniques can be used to decrease or eliminate diffusion density limitations, which can result in achieving ultra-high-density ROM.

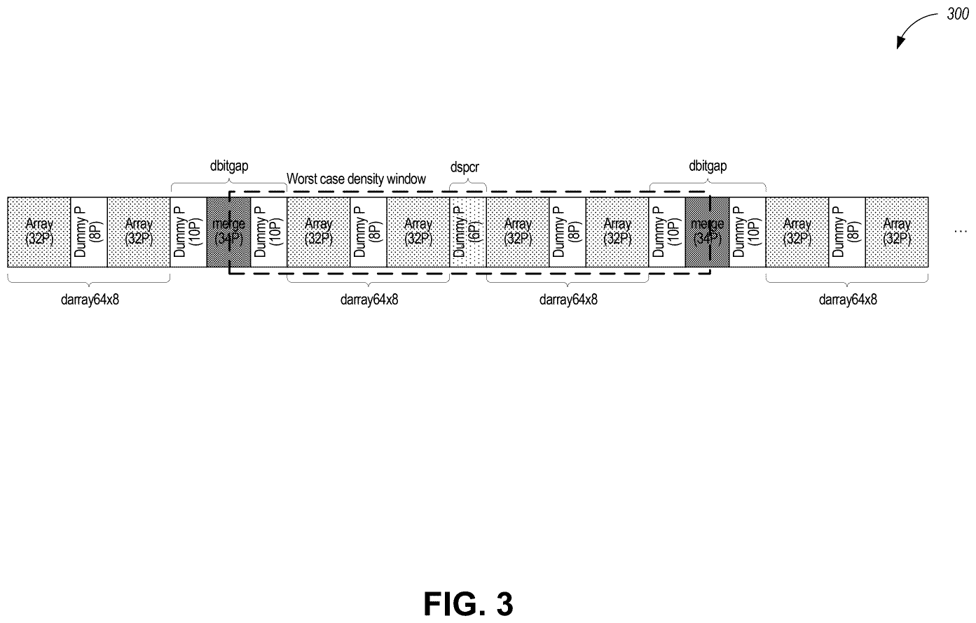

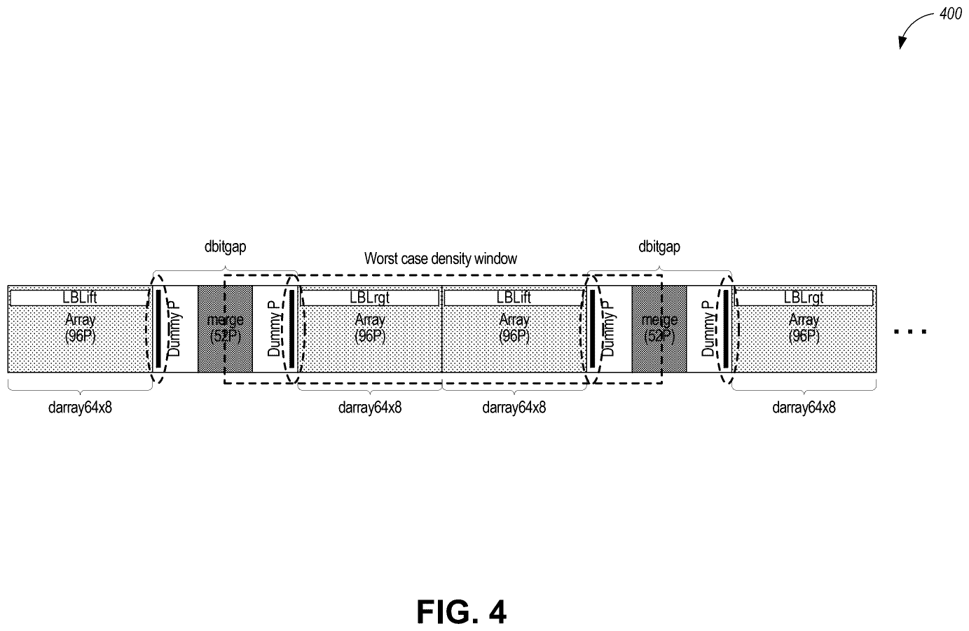

In some aspects, the ROM issue can be resolved by placing dummy P/N devices with extra area growth. Dummy devices are planned and placed the way shown in FIG. 3 and FIG. 4 in two consecutive nodes (N and N+1) to address max and min diffusion densities where only N-type ROM bit-cells are used.

The solution for node N ROM is shown in FIG. 3.

FIG. 3 is a block diagram 300 of a horizontal bit-slice placement of dummy P-diffusion in node N ROM solution for node N+1 ROM, in accordance with some embodiments.

In node N ROM, array density is cleaned by preferring dummy P-diffusion horizontally to avoid extra cap in read word lines (RWL), which is shown in FIG. 3. Apart from bit-cell N devices (128pp), another 88pp is kept to place other logic and dummy devices. In this, 88pp 42pp was used for dummy P-diffusion in each X dimension of the density window. That is 19% of 216pp (X dimension of density window).

The solution for node N+1 ROM is shown in FIG. 4.

FIG. 4 is a block diagram 400 of horizontal bit-slice placement of dummy P-diffusion for array slice with node N+1 ROM, in accordance with some embodiments.

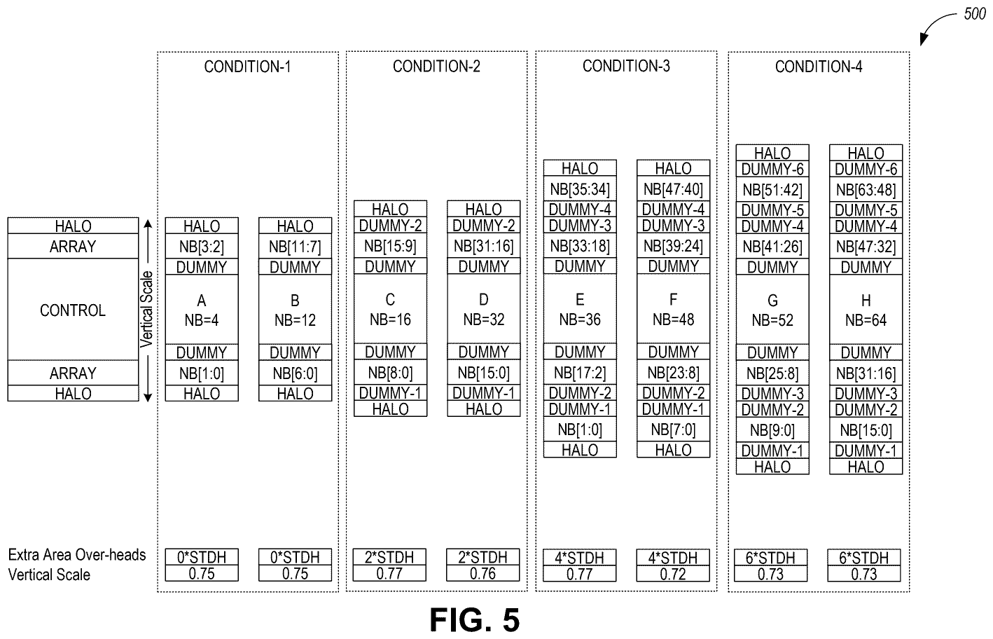

In the node N+1 ROM, as bit-cell X is increased by 50%, placing dummy P only horizontally is not an optimized option. Moreover, metal length restriction for the horizontal path (especially for GBL) is essential to give preference to the high restive path for avoiding Vmax and performance degradation issues. Dummy P diffusion placement is also given preference in the vertical direction as bit-cell height is reduced by 25%. Multiple combinations are explored, and an optimum area-efficient solution is achieved by considering dummy P diffusion for both directions-horizontal as well as vertical. Horizontal side dummy P is filled only in the bitmap cell (shown in FIG. 4), and the remaining density issues are addressed by controlling extra dummy P slices in a vertical direction (shown in FIG. 5).

FIG. 5 is a block diagram 500 of the vertical placement of dummy P-diffusion for node N+1 ROM along with horizontal placement, in accordance with some embodiments.

For further area improvement, P dummy slices with different conditions can be placed rather than placing them blanket. All conditions are calculated by mathematical analysis to serve the entire compiler range. As an example, only 4 conditions are shown in FIG. 5, but other conditions can be created to satisfy the density clean solution for the entire compiler level by covering multiple compiler features. It creates extra complexity for the software side to enable all conditions and generate instances with the right combinations from the compiler.

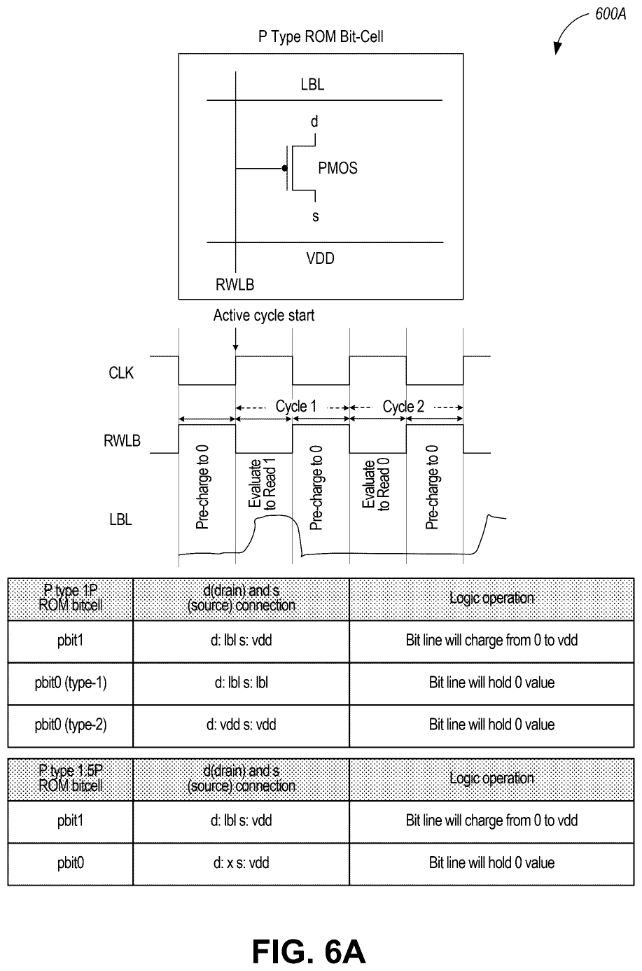

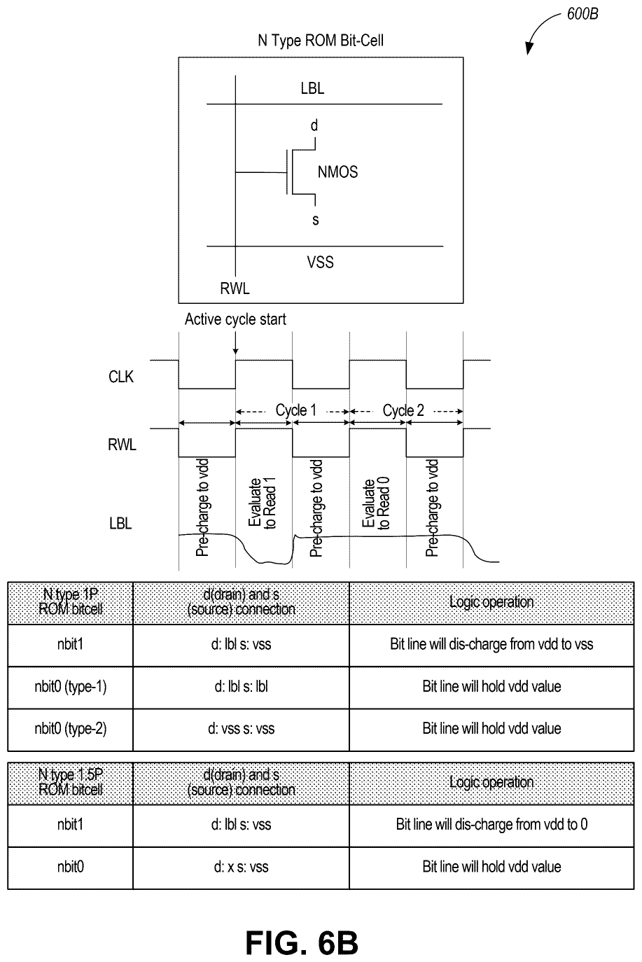

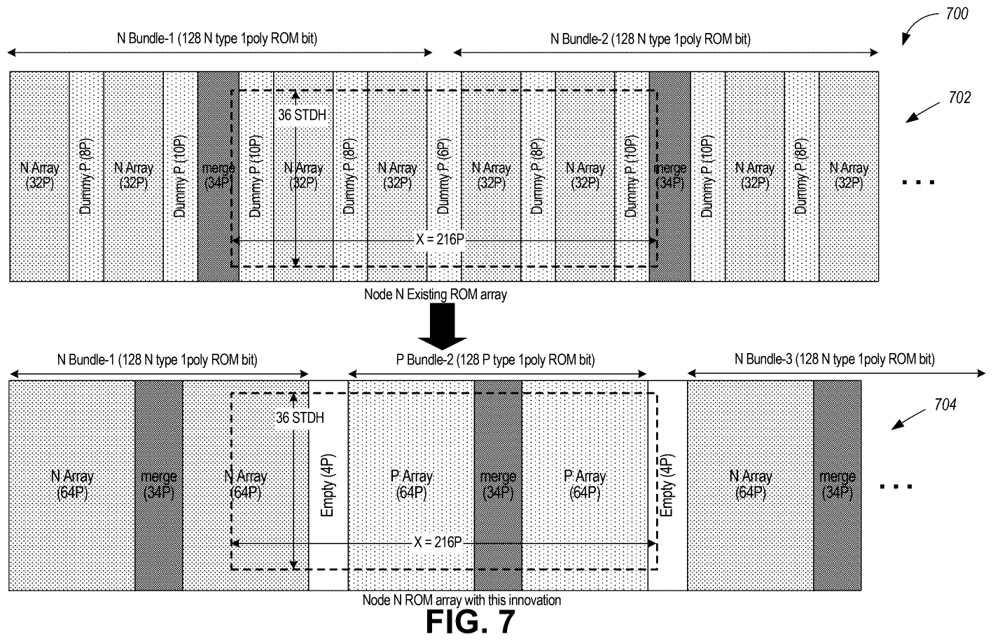

The disclosed techniques include a new P-type bit-cell along with conventional N-type bit cells in the array. This technique can be used to balance the P and N diffusion ratio at the memory array level for embedded ROM and help to remove the max and min diffusion density limitations. The disclosed technique can include configurations where N and P-type arrays are placed horizontally in every alternate bundle in the same bit slice, and the solution of full array architecture planning will be described herein below. The basic functionality of both N and P-type ROM bit-cells are described in FIG. 6A and FIG. 6B, for both 1P and 1.5P PROM bit-cells.

FIG. 6A and FIG. 6B are corresponding block diagrams 600A and 600B of the functionality of both N and P-type PROM bit-cells, in accordance with some embodiments.

With numerous advanced AI projects underway, there is an expectation that the use of ROM will rise substantially. Recent studies suggest that in applications involving Large Language Models (LLMs), ROM could account for over half of the chip's real estate. Consequently, the industry is turning its attention to the development of programmable ROMs that are both ultra-high-density and low-power. Innovations in this domain are poised to support the integration of greater amounts of ROM memory into the system-on-chips (SoCs) of the future, particularly for applications that leverage LLMs. The disclosed techniques can be used to save an additional 10% to 16.5% area over conventional ROM design.

FIG. 7 is a block diagram 700 of an array floor plan before and after the application of the disclosed techniques with 1 poly ROM bit-cells in Node N, in accordance with some embodiments. FIG. 7 illustrates an existing ROM array 702 for node N and ROM array 704 for node N configured with the disclosed techniques.

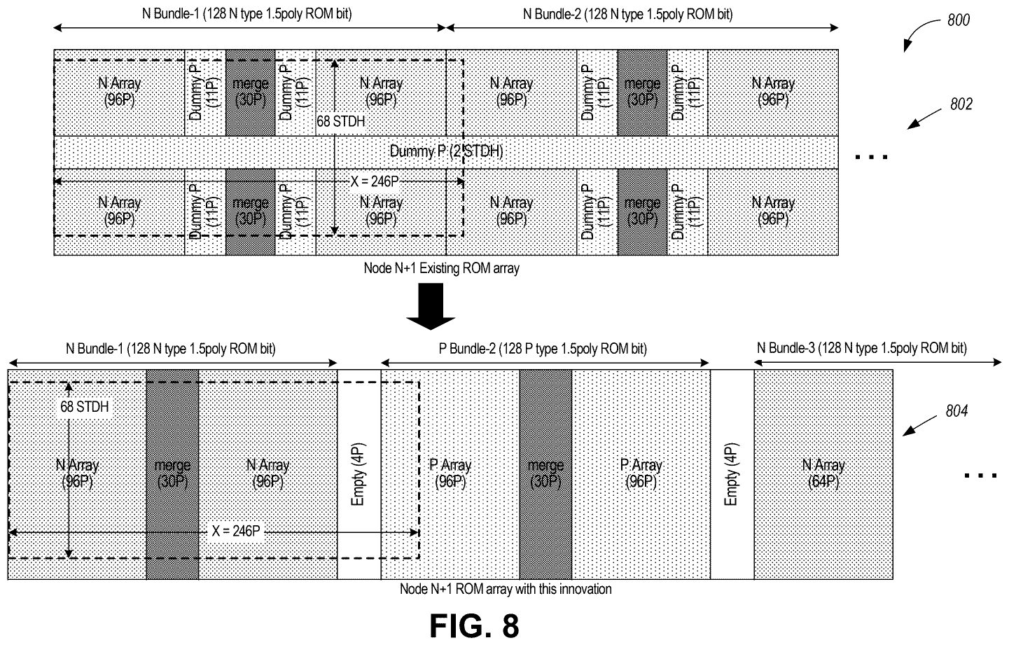

FIG. 8 is a block diagram 800 of an array floor plan before and after the application of the disclosed techniques with 1.5 poly ROM bit-cells in Node N+1, in accordance with some embodiments. FIG. 8 illustrates an existing ROM array 802 for node N+1 and ROM array 804 for node N+1 configured with the disclosed techniques.

In the disclosed techniques, each bit slice (referring to FIG. 3 and FIG. 4) uses P and N bundles alternately. FIG. 7 and FIG. 8 further illustrate where the N-bundle will be followed by the P-bundle. Each bundle can support 128 bit-cells and 64 bits per local bit line (LBL). FIG. 7 and FIG. 8 show before and after the application of the disclosed techniques what changes can be configured in array floor plans in node N and node N+1, respectively. Examples with both 1 poly and 1.5 poly bit-cells in two consecutive nodes (N and N+1) are provided in FIG. 7 and FIG. 8 respectively. With the disclosed techniques, the array floor plan will remain the same irrespective of bit-cell type or process node changes, and it will reduce array optimization efforts significantly because diffusion density violation is taken care of architecturally with usages of alternate bundles of two bit-cell types N and P.

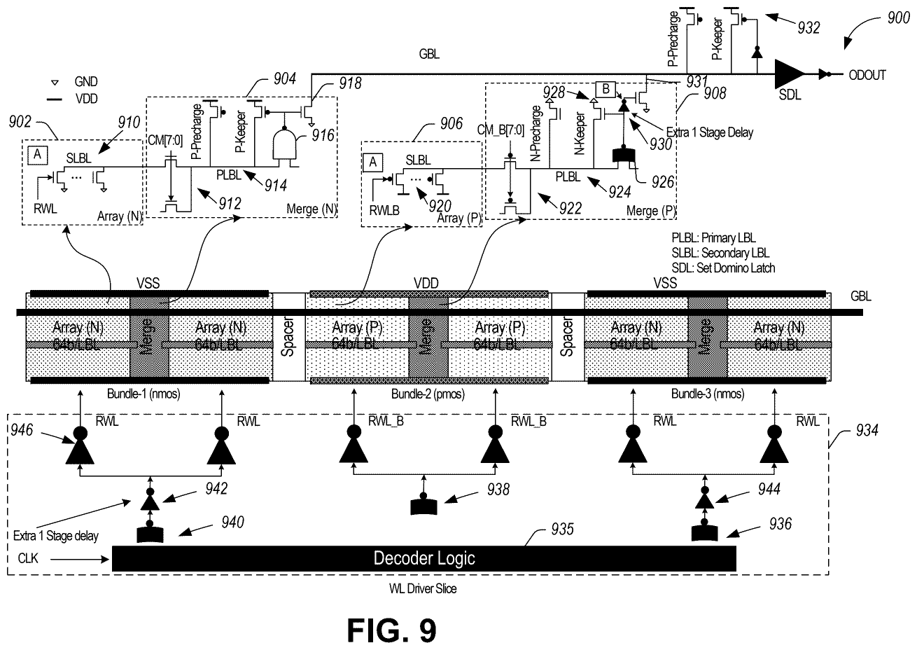

FIG. 9 is a block diagram of circuit 900 supporting both N and P-type bit-cells in a horizontal direction of a bit slice, in accordance with some embodiments.

Referring to FIG. 9, circuit 900 can include NMOS-based bundles of N-based memory arrays (e.g., Bundle-1 and Bundle-3) and a PMOS-based bundle of P-based memory arrays (e.g., Bundle-2 configured between Bundle-1 and Bundle-3).

Bundle-1 can include N-based arrays coupled via a merge circuit. For example, Bundle-1 includes array 902 and merge circuit 904, and Bundle-2 includes array 906 and merge circuit 908.

Array 902 includes a set of NMOS transistors 910 coupled in parallel with each other. Merge circuit 904 includes a set of NMOS transistors 912, a set of PMOS transistors 914, a NAND gate 916, and an NMOS transistor 918.

Array 906 includes a set of PMOS transistors 920 coupled in parallel with each other. Merge circuit 908 includes a set of PMOS transistors 922, a set of NMOS transistors 924, a NOR gate 926, a buffer circuit 9281328, a delay circuit 930, and an NMOS transistor 931.

Merge circuits 904 and 908 are coupled to a global bitline (GBL) via NMOS transistors 918 and 931. The GBL is coupled to a set of PMOS transistors 932.

Circuit 900 also includes a wordline (WL) driver slice 934, which includes decoder logic 935, NOR gates 936, 938, and 940, delay circuits 942, 944, and 946.

FIG. 9 shows circuit changes based on the disclosed techniques. For example, Bundle-1 is driven by N-type bit-cells, and the merge cell is designed accordingly with P-type pre-charge and keeper circuits. Read operation is domino logic based. LBL of bundle-1 will be pre-charged in every clock cycle to a high (VDD) value and when RWL is going to high, the N-type bit-cell (nbit1, referring to FIG. 6) will turn ON and discharge the LBL through bit-cell N device in read-1 operation whereas in read-0 operation bit-cell type will be nbit0, there will not be any path to discharge so LBL will hold to high value through a keeper. After Bundle-1, Bundle-2 will be placed, which is driven by P-type bit-cells. Here, the merge cell is designed with reverse polarity for the domino-1 circuit (N-type pre-charge and keeper circuit), but the global pull-down control polarity is kept the same by adding an extra inverter, and the Domino-2 logics are matched across all band.

As illustrated in FIG. 9, an extra inverter is used for the N-type array just before the RWL driver, and for the P-type array, that inverter is added in the merged cell to match the clock to q delay between two arcs (read path-driven by N type and P type bit-cell).

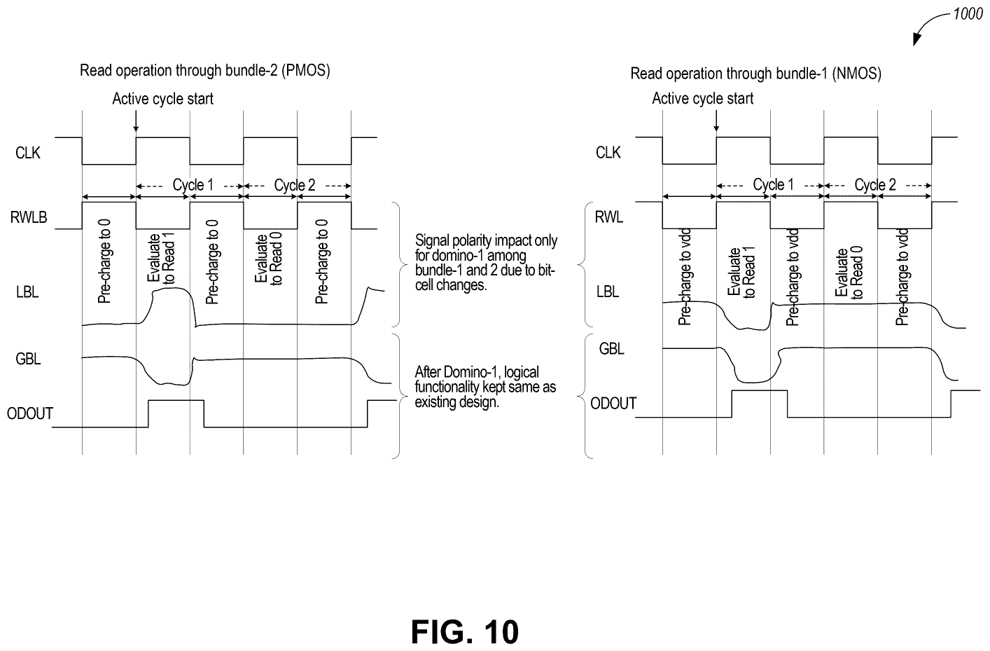

FIG. 10 illustrates a diagram 1000 of read functionality changes among two bundles, in accordance with some embodiments. Both the bundles behave the same way after Domino-1.

Table 1 below illustrates area impact for both two types of nodes (e.g., N and N+1 nodes). Data shows that the disclosed techniques can save about 10% to 16.5% of area. For high density (MB/mm²) ROM design, the disclosed techniques can be used to support high volume ROM usages in futuristic AI applications.

Table 2 below illustrates preliminary data on performance and power. This will improve leakage power as 50% bit-cell will be PMOS (PMOS is less leaky than NMOS). Simultaneously, it may degrade performance by about 10%. However, these are design fine tuning parameters that can be taken care in actual design implementation.

Table 1 is as follows:

TABLE 1

| | | | | Area | Density |
|---|---|---|---|---|---|
| Option | Bit Cell | NW | NB | Scale | MB/mm2 |
| N Node | 1P V0 only N type | 16384 | 40 | 1 | 10.938 |
| conventional | ROM bitcell | | | | |
| ROM | (1*P)*(0.5*STDH) | | | | |
| (16384 × 40) | | | | | |
| N node ROM | 1P V0 both N and P | 16384 | 40 | 0.835 | 13.095 |
| (16384 × 40) | type ROM bitcell | | | | |
| with innovation | (1*P)*(0.5*STDH) | | | | |
| N + 1 node | 1.5P V1 only N-type | 16384 | 64 | 1 | 12.315 |
| conventional | ROM bitcell | | | | |
| ROM | (1.5*P)*(0.5*STDH) | | | | |
| (16384 × 64) | | | | | |
| N + 1 node | 1.5P V1 both N and | 16384 | 64 | 0.906 | 13.593 |
| ROM | P-type ROM bit | | | | |
| (16384 × 64) | cells | | | | |
| with innovation | (1.5*P)*(0.5*STDH) | | | | |

Table 2 is as follows:

TABLE 2

| | | | | | | | Cycle |
|---|---|---|---|---|---|---|---|
| | | | | | Pleak_all | Pread_typ | time |
| Option | PVT | | NW | NB | (Scale) | (Scale) | (Scale) |
| N + 1 node | 0.6 | V | 6400 | 48 | 1 | 1 | 1 |
| ROM | TT | | | | | | |
| (6400 × 48) | 25 | C | | | | | |
| N + 1 node | 0.6 | V | 6400 | 48 | 0.79 | 1 | 1.1 |
| ROM | TT | | | | | | |
| (6400 × 48) | 25 | C | | | | | |
| with | | | | | | | |
| innovation | | | | | | | |

The disclosed techniques described below relate to diffusion density resist multi-bits PROM for ultra-high-density embedded ROM.

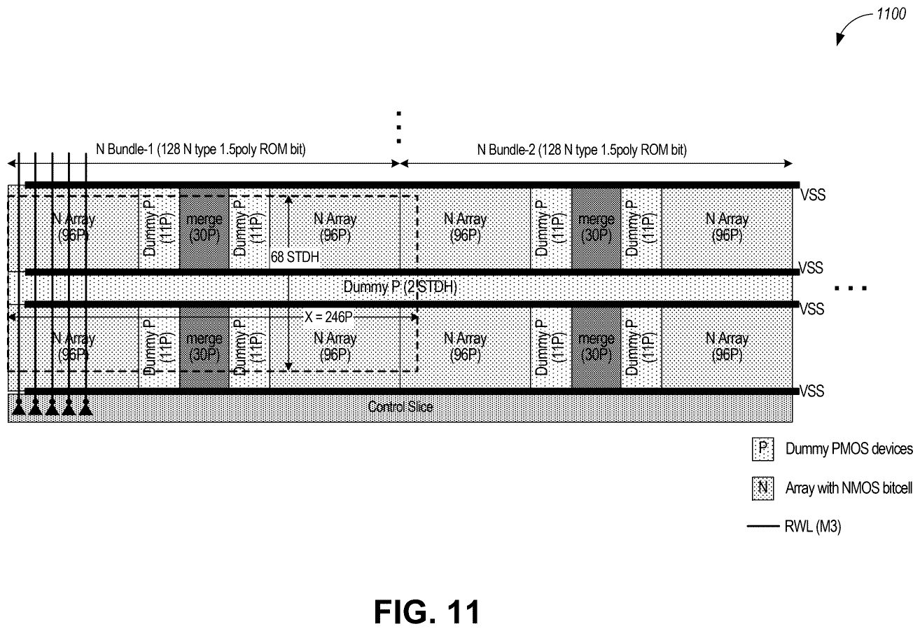

FIG. 11 is an example ROM floor plan 1100, in accordance with some embodiments.

In some aspects, two types of bit slices can be used-N-type and P-type bit slices. They can be placed vertically by maintaining 50% N and P bit slices within any density window.

FIG. 11 illustrates an example ROM floor plan where all bit slices are with N-type bit-cells only, and a density clean solution is achieved by consideration of dummy P diffusions. In some aspects, read wordline (RWL) is used to drive N-type bit-cells.

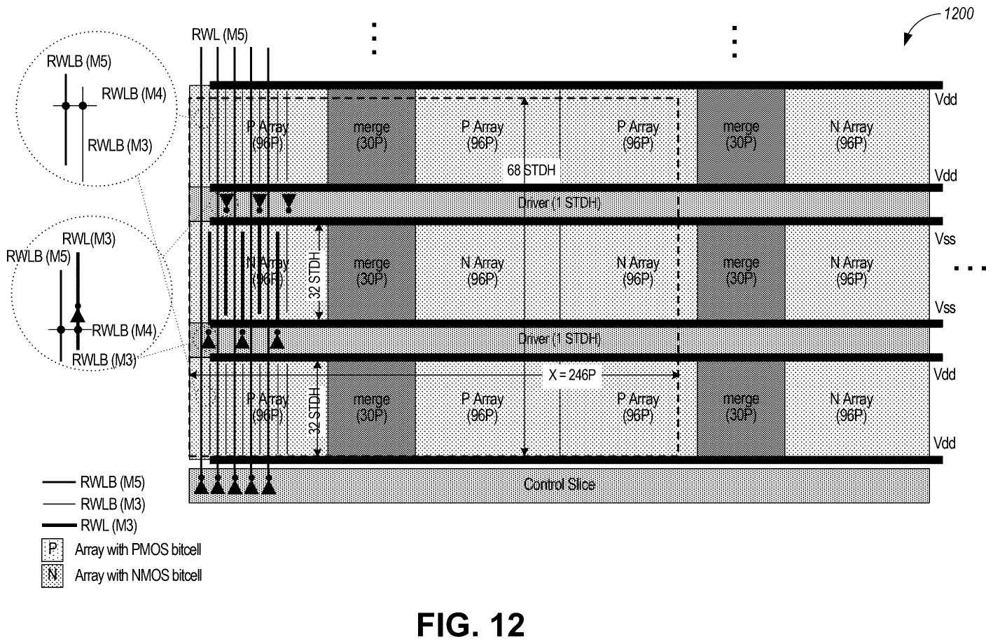

FIG. 12 is an example multibit ROM floor plan 1200 based on the disclosed techniques, in accordance with some embodiments. Referring to FIG. 12, P and N-type arrays are placed alternately in a vertical direction every 32 standard cell height (STDH). Presently, 32 STDH is calculated by considering 50% of diffusion density window height (50% of 68 STDH, it is 34 STDH) and bit-slice counts (8-bit slices can be placed in 32 STDH). This number may change based on technology and bit-cell height, but the concept of this calculation will be the same.

In some aspects, dual polarity (RWL and RWL bar (RWLB)) of read word lines can be used to access both N and P-type bit-cells. In some aspects, bit-cells of P-type bit-slices are directly controlled by RWLB through M5 (metal 5) and derived RWL through a local inverter to access all bit-cells of N-type bit-slices.

In some aspects, STDH driver slices are accounted for by both the top and bottom of N-type slices only by consideration of power tracks and layout constraints. This solution may not need any separation cell to separate among two bundles as P and N-type slices are placed vertically.

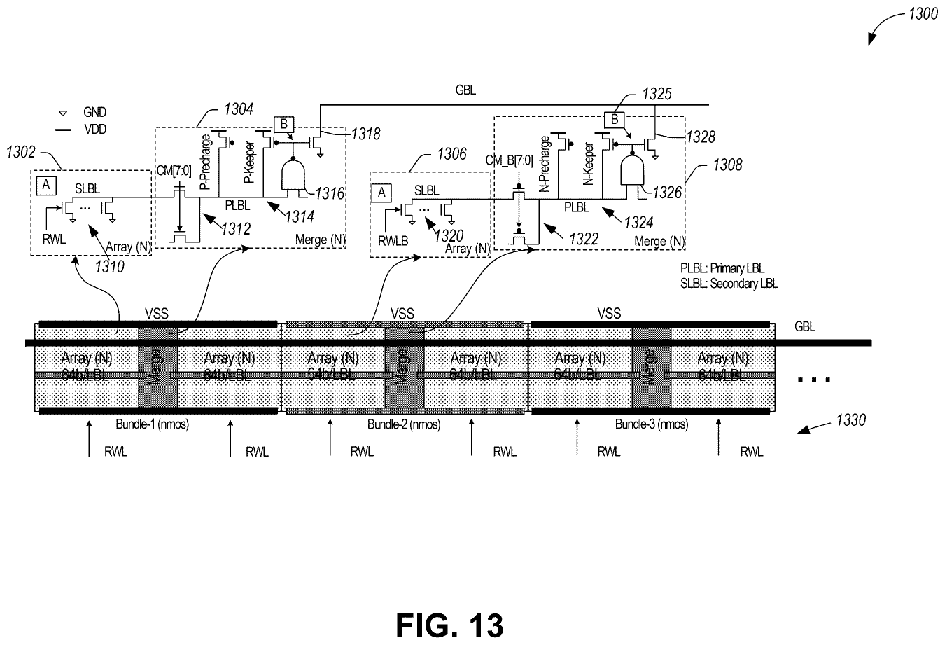

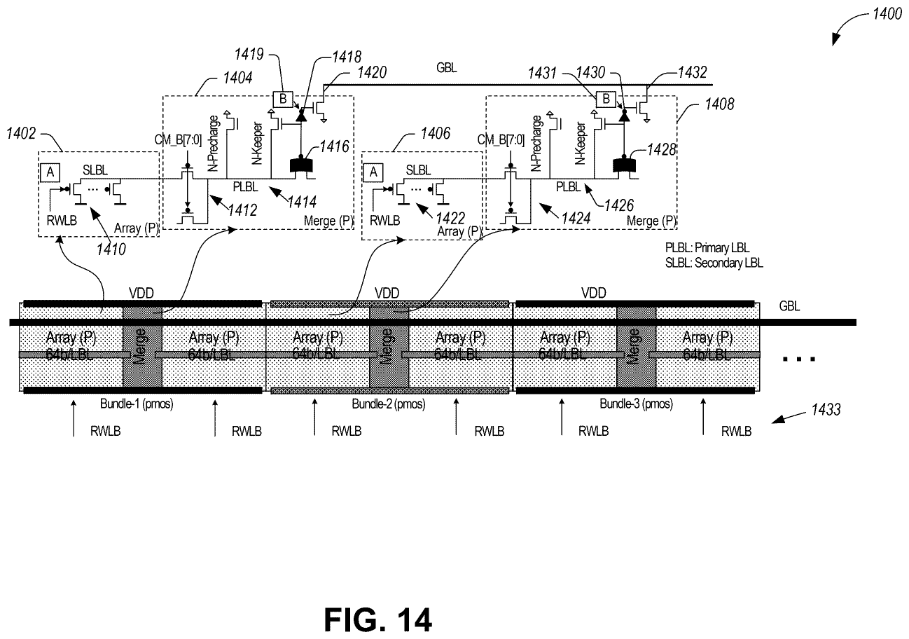

Actual circuit implementations of both N and P-type bit-slices are shown in FIG. 13 and FIG. 14 using the disclosed techniques.

FIG. 13 is an example circuit behavior of an N-type bit slice 1300, in accordance with some embodiments. Referring to FIG. 13, the N-type bit slice 1300 includes NMOS-based bundles such as Bundle-1, Bundle-2, and Bundle-3. FIG. 13 illustrates partial details of Bundle-1 and Bundle-2 for convenience.

Bundle-1 includes array 1302 and merge circuit 1304. Array 1302 includes a set of NMOS transistors 1310 coupled in parallel with each other. Merge circuit 1304 includes a set of NMOS transistors 1312, a set of PMOS transistors 1314, a NAND gate 1316, a buffer circuit B, and an NMOS transistor 1318.

Bundle-2 includes array 1306 and merge circuit 1308. Array 1306 includes a set of NMOS transistors 1320 coupled in parallel with each other. Merge circuit 1308 includes a set of PMOS transistors 1322, a set of PMOS transistors 1324, a NAND gate 1326, a buffer circuit 1325, and an NMOS transistor 1328.

Merge circuits 1304 and 1308 are coupled to a GBL terminal via NMOS transistors 1318 and 1328.

N-type bit slice 1300 also includes read wordline (RWL) terminals 1330 coupled to Bundle-1, Bundle-2, and Bundle-3.

FIG. 14 is an example circuit behavior of a P-type bit slice 1400, in accordance with some embodiments. Referring to FIG. 14, the P-type bit slice 1400 includes PMOS-based bundles such as Bundle-1, Bundle-2, and Bundle-3. FIG. 14 illustrates partial details of Bundle-1 and Bundle-2 for convenience.

Bundle-1 includes array 1402 and merge circuit 1404. Array 1402 includes a set of PMOS transistors 1410 coupled in parallel with each other. Merge circuit 1404 includes a set of PMOS transistors 1412, a set of NMOS transistors 1414, a NOR gate 1416, a buffer circuit 1419, a delay circuit 1418, and an NMOS transistor 1420.

Bundle-2 includes array 1406 and merge circuit 1408. Array 1406 includes a set of PMOS transistors 1422 coupled in parallel with each other. Merge circuit 1408 includes a set of PMOS transistors 1424, a set of NMOS transistors 1426, a NOR gate 1428, a buffer circuit 1431, a delay circuit 1430, and an NMOS transistor 1432.

Merge circuits 1404 and 1408 are coupled to a GBL terminal via NMOS transistors 1420 and 1432.

N-type bit slice 1300 also includes read wordline (RWL) terminals 1433 coupled to Bundle-1, Bundle-2, and Bundle-3.

In reference to FIG. 13 and FIG. 14, the N-type bit slice is driven by N-type bit-cells, and the merge cell is designed with P-type pre-charge and keeper circuits. A read operation is domino logic-based. Local bitline (LBL) can be pre-charged in every clock cycle to a high (VDD) value, and when RWL is going to high, and N-type bit-cell (nbit1, referring to FIG. 6) will turn ON and discharge the LBL through bit-cell N device in read-1 operation. In a read-O operation, the bit-cell type will be nbit0; there will not be any path to discharge, so LBL will hold to high value through the keeper. Similarly, the P-type bit slice is driven by P-type bit-cells, and the merge cell is designed with reverse polarity for domino-1 circuits with N-type pre-charge and keeper circuits. A global pull-down is kept as an NMOS device for a P-type bit slice also by adding an extra inverter at the output of the NOR gate. In this way, the polarity of domino-2 signals is kept the same for both P and N-type bit-slices. In some aspects, interface timing can be kept the same as conventional ROM design.

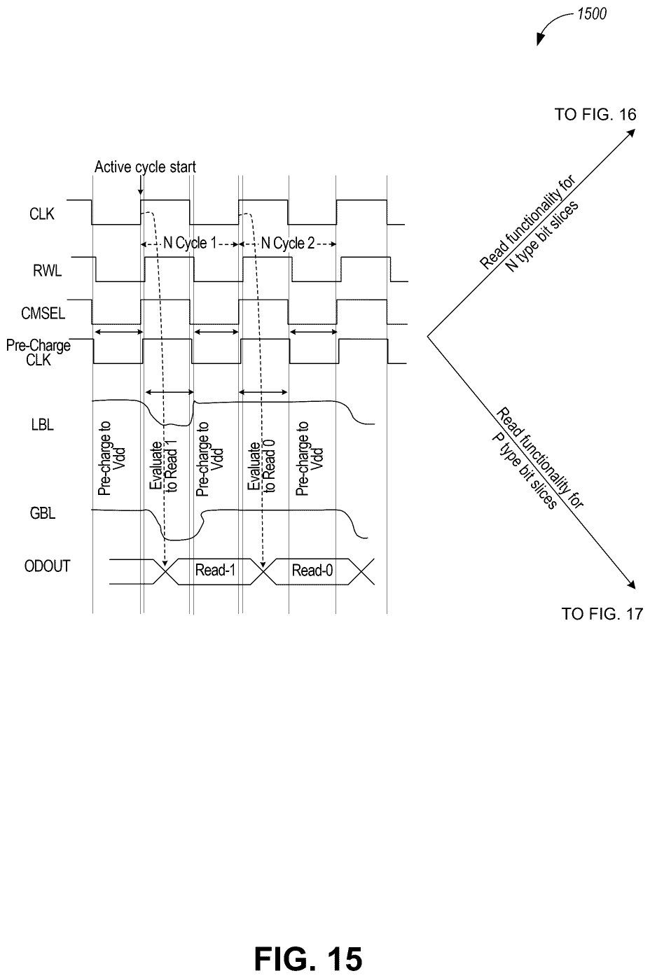

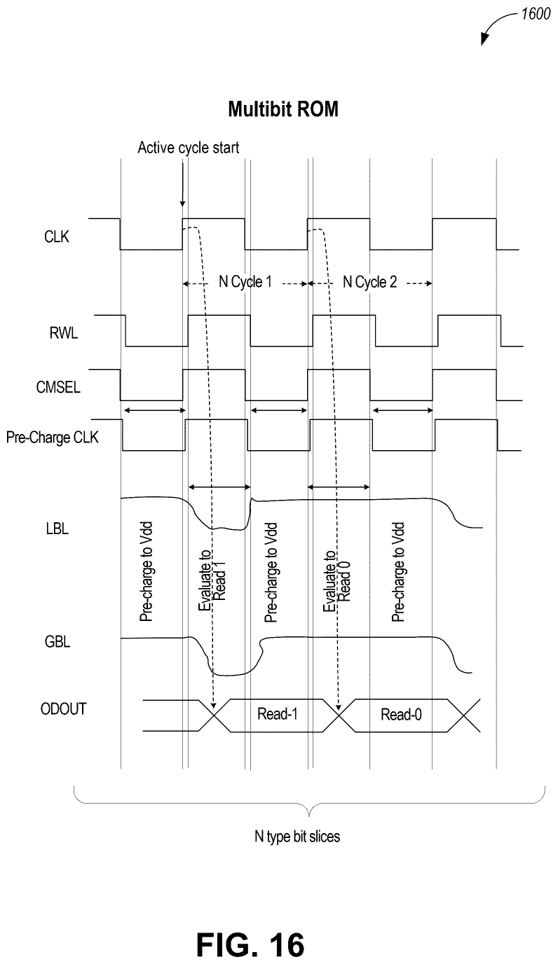

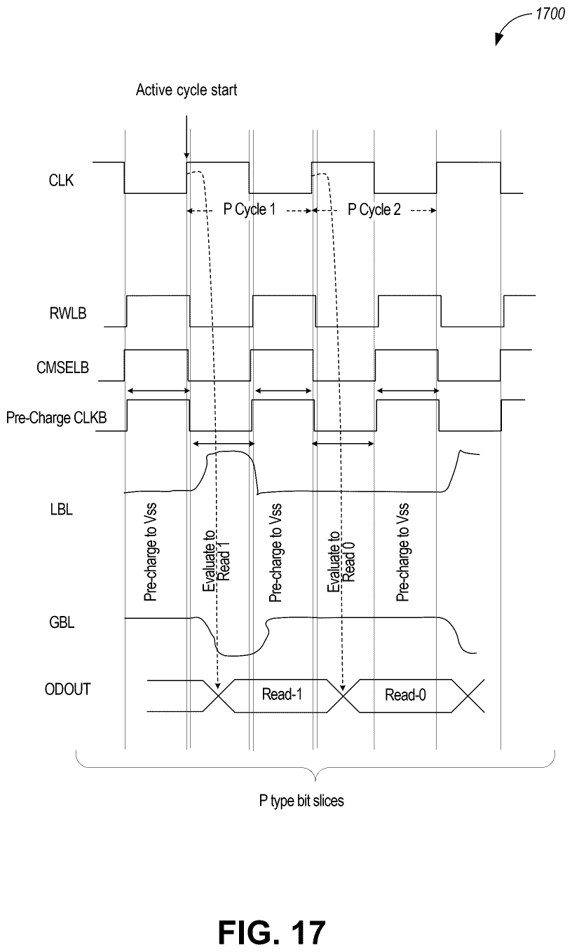

In some aspects, the disclosed bit slices can be configured using a balanced clock-to-q (TCQ) delay between P and N-type bit slices. In N-type bit-slice, after generating RWLB (which is read word line for P-type bit slices), an extra inverter is used to generate RWL for N-type bit slices. This extra one-stage inverter delay is compensated in merge (P) after the NOR gate of the P-type bit-slice. FIGS. 15-17 show read functionality changes among two slices. Both slices can be configured to behave the same way after Domino-1.

FIG. 15, FIG. 16, and FIG. 17 illustrate corresponding diagrams 1500, 1600, and 1700 of read functionality changes among two slices for a multi-bit ROM, in accordance with some aspects.

Table 3 below illustrates area impact (e.g., in an N+1 node). As seen from Table 3, the disclosed techniques can be used to save an area of about 11% to 14.1%. For high-density (MB/mm2) ROM design, the disclosed techniques can be used to support high-volume ROM usage in AI applications.

Table 2 also illustrates preliminary data on performance and power numbers. The disclosed techniques can improve leakage power, as 50% of the bit cells will be PMOS (PMOS is less leaky than NMOS).

Table 3 is as follows:

TABLE 3

| | | | | Area | Density |
|---|---|---|---|---|---|
| Option | Bit Cell | NW | NB | Scale | MB/mm2 |
| N + 1 node | 1P V0 only N-type | 16384 | 80 | 1 | 12.107 |
| conventional | ROM bitcell | | | | |
| ROM | (1*P)*(0.5*STDH) | | | | |
| (16384 × 80) | | | | | |
| N + 1 node | 1P V0 both N and P- | 16384 | 80 | 0.859 | 14.088 |
| ROM | type ROM bitcell | | | | |
| (16384 × 80) | (1*P)*(0.5*STDH) | | | | |
| with | | | | | |
| innovation | | | | | |
| N + 1 node | 1.5P V1 only N-type | 16384 | 64 | 1 | 12.315 |
| conventional | ROM bitcell | | | | |
| ROM | (1.5*P)*(0.5*STDH) | | | | |
| (16384 × 64) | | | | | |
| N + 1 node | 1.5P V1 both N and | 16384 | 64 | 0.899 | 13.703 |
| ROM | P-type ROM bit | | | | |
| (16384 × 64) | cells | | | | |
| with | (1.5*P)*(0.5*STDH) | | | | |
| innovation | | | | | |

The disclosed techniques are associated with the following advantages:
(a) There will not be any extra area overheads due to diffusion density clean-up, which is a bottleneck in today's ROM design.
(b) Reduce design/layout efforts as the disclosed techniques will nullify diffusion density limitations.
(c) The disclosed techniques will not change any interface timing characteristics with respect to existing ROM designs. The disclosed changes will be internal design implementations at an array level.
(d) The disclosed configurations are easy to integrate at the bit slice level because this solution impacts Domino-1 logic that relates to half of the array, but signal polarity can be kept the same at the Domino-2 level when two bundles are going to be merged through the GBL.
(e) The disclosed techniques are technology-friendly as they comply with critical layout rules (e.g., DRCDs).
(f) The disclosed techniques can be used to achieve optimal array density with minimal performance loss. AI application ROM performance is presented as a lower priority than array density and power.

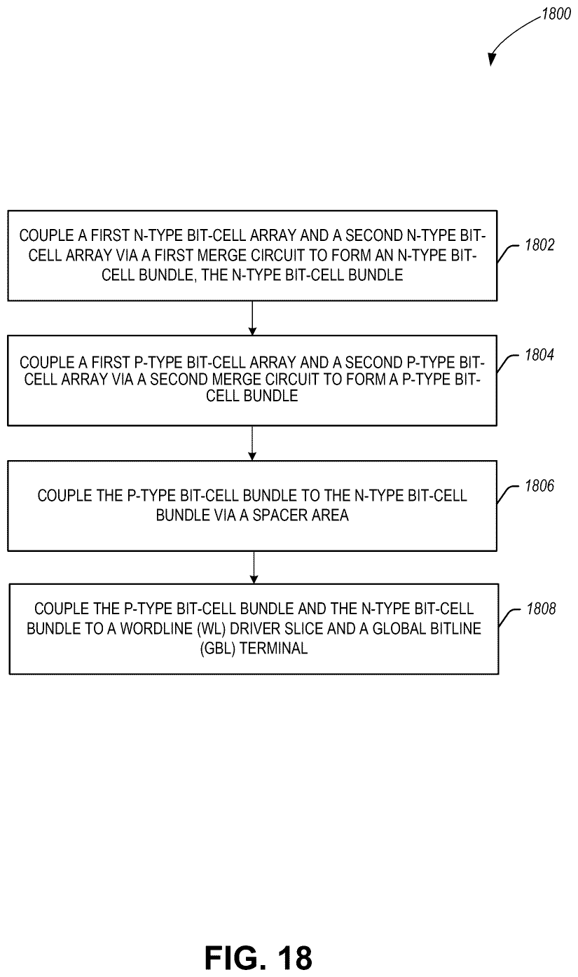

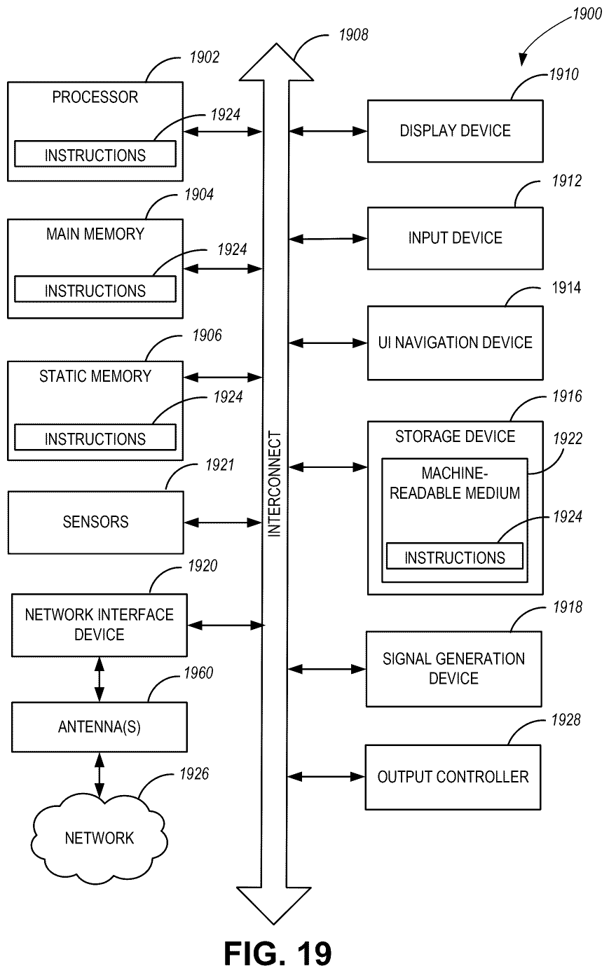

FIG. 18 is a flow diagram of an example method 1800 for manufacturing a memory bit-cell array, in accordance with some embodiments. Referring to FIG. 18, method 1800 includes operations 1802, 1804, 1806, and 1808, which may be executed by a processor, an embedded controller, a receiver circuit, a transceiver circuit, or another processor of a computing device (e.g., hardware processor 1902 of machine 1900 illustrated in FIG. 19, which can include one or more of the circuits discussed in connection with FIGS. 1-17). In some embodiments, one or more of the circuits discussed in connection with FIGS. 1-17 can perform the functionalities (or include the configurations or circuitry) associated with FIG. 18, as well as one or more of the examples listed below.

At operation 1802, a first N-type bit-cell array and a second N-type bit-cell array are coupled via a first merge circuit to form an N-type bit-cell bundle;

At operation 1804, a first P-type bit-cell array and a second P-type bit-cell array are coupled via a second merge circuit to form a P-type bit-cell bundle.

At operation 1806, the P-type bit-cell bundle is coupled to the N-type bit-cell bundle via a spacer area.

At operation 1808, the P-type bit-cell bundle and the N-type bit-cell bundle are coupled to a wordline (WL) driver slice and a global bitline (GBL) terminal.

FIG. 19 illustrates a block diagram of an example machine 1900 upon which any one or more of the techniques (e.g., methodologies) discussed herein may perform. In alternative embodiments, the machine 1900 may operate as a standalone device or may be connected (e.g., networked) to other machines. In a networked deployment, machine 1900 may operate in the capacity of a server machine, a client machine, or both in server-client network environments. In an example, machine 1900 may function as a peer machine in a peer-to-peer (P2P) (or other distributed) network environment. The machine 1900 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 1900 may include a hardware processor 1902 (e.g., a central processing unit (CPU), a graphics processing unit (GPU), a hardware processor core, or any combination thereof), a main memory 1904, and a static memory 1906, some or all of which may communicate with each other via an interlink (e.g., bus) 1908. In some aspects, the main memory 1904, the static memory 1906, or any other type of memory (including cache memory) used by machine 1900 can be configured based on the disclosed techniques or can implement the disclosed memory devices.

Specific examples of main memory 1904 include Random Access Memory (RAM) and semiconductor memory devices, which may include, in some embodiments, storage locations in semiconductors such as registers. Specific examples of static memory 1906 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1900 may further include a display device 1910, an input device 1912 (e.g., a keyboard), and a user interface (UI) navigation device 1914 (e.g., a mouse). In an example, the display device 1910, the input device 1912, and the UI navigation device 1914 may be a touchscreen display. The machine 1900 may additionally include a storage device (e.g., drive unit or another mass storage device) 1916, a signal generation device 1918 (e.g., a speaker), a network interface device 1920, and one or more sensors 1921, such as a global positioning system (GPS) sensor, compass, accelerometer, or other sensors. The machine 1900 may include an output controller 1928, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 1902 and/or instructions 1924 may comprise processing circuitry and/or transceiver circuitry.

The storage device 1916 may include a machine-readable medium 1922 on which one or more sets of data structures or instructions 1924 (e.g., software) embodying or utilized by any one or more of the techniques or functions described herein can be stored. Instructions 1924 may also reside, completely or at least partially, within the main memory 1904, within static memory 1906, or the hardware processor 1902 during execution thereof by machine 1900. In an example, one or any combination of the hardware processor 1902, the main memory 1904, the static memory 1906, or the storage device 1916 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1922 is illustrated as a single medium, the term “machine-readable medium” may include a single medium or multiple media (e.g., a centralized or distributed database and/or associated caches and servers) configured to store instructions 1924.

An apparatus of machine 1900 may be one or more of a hardware processor 1902 (e.g., a central processing unit (CPU), a graphics processing unit (GPU), a hardware processor core, or any combination thereof), a main memory 1904 and a static memory 1906, one or more sensors 1921, a network interface device 1920, one or more antennas 1960, a display device 1910, an input device 1912, a UI navigation device 1914, a storage device 1916, instructions 1924, a signal generation device 1918, and an output controller 1928. The apparatus may be configured to perform one or more of the methods and/or operations disclosed herein. The apparatus may be intended as a component of machine 1900 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 1900 and that causes machine 1900 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1924 may further be transmitted or received over a communications network 1926 using a transmission medium via the network interface device 1920 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.8.4 family of standards, a Long Term Evolution (LTE) family of standards, a Universal Mobile Telecommunications System (UMTS) family of standards, peer-to-peer (P2P) networks, among others.

In an example, the network interface device 1920 may include one or more physical jacks (e.g., Ethernet, coaxial, or phone jacks) or one or more antennas to connect to the communications network 1926. In an example, the network interface device 1920 may include one or more antennas 1960 to wirelessly communicate using at least one single-input multiple-output (SIMO), multiple-input multiple-output (MIMO), or multiple-input single-output (MISO) techniques. In some examples, the network interface device 1920 may wirelessly communicate using multiple-user MIMO techniques. The term “transmission medium” shall be taken to include any intangible medium that can store, encode, or carry instructions for execution by machine 1900 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, examples that include the elements shown or described are also contemplated. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar, although the scope of the disclosure is not limited in this respect.

Described implementations of the subject matter can include one or more features, alone or in combination, as illustrated below by way of examples.

Example 1 is a memory circuit comprising: a first set of NMOS transistors comprising a corresponding set of source terminals, the first set of NMOS transistors coupled in parallel with each other via the corresponding set of source terminals of the first set of NMOS transistors; a first set of PMOS transistors comprising a corresponding set of source terminals, the first set of PMOS transistors coupled in parallel with each other via the corresponding set of source terminals of the first set of PMOS transistors, and a gate terminal of at least one of the first set of PMOS transistors coupled to a global bitline (GBL) terminal; a second set of PMOS transistors comprising a corresponding set of source terminals, the second set of PMOS transistors coupled in parallel with each other via the corresponding set of source terminals of the second set of PMOS transistors; and a second set of NMOS transistors comprising a corresponding set of source terminals, the second set of NMOS transistors coupled in parallel with each other via the corresponding set of source terminals of the second set of NMOS transistors, and a gate terminal of at least one of the second set of NMOS transistors coupled to the GBL terminal.

In Example 2, the subject matter of Example 1 includes, a third set of NMOS transistors, wherein a drain terminal of at least one NMOS transistor of the third set of NMOS transistors is coupled to the corresponding set of source terminals of the first set of NMOS transistors, and wherein a source terminal of the at least one NMOS transistor of the third set of NMOS transistors is coupled to the corresponding set of source terminals of the first set of PMOS transistors.

In Example 3, the subject matter of Example 2 includes, a third set of PMOS transistors, wherein a drain terminal of at least one PMOS transistor of the third set of PMOS transistors is coupled to the corresponding set of source terminals of the second set of PMOS transistors, and wherein a source terminal of the at least one PMOS transistor of the third set of PMOS transistors is coupled to the corresponding set of source terminals of the second set of NMOS transistors.

In Example 4, the subject matter of Examples 2-3 includes, wherein source terminals of the third set of NMOS transistors are coupled to a primary local bitline (PLBL) terminal.

In Example 5, the subject matter of Example 4 includes, a NAND gate, wherein an input terminal of the NAND gate is coupled to the PLBL and the corresponding set of source terminals of the first set of PMOS transistors.

In Example 6, the subject matter of Example 5 includes, a coupling NMOS transistor, wherein a source terminal of the coupling NMOS transistor is coupled to the GBL terminal, a gate terminal of the coupling NMOS transistor is coupled to a gate terminal of at least one PMOS transistor of the first set of PMOS transistors and an output terminal of the NAND gate.

In Example 7, the subject matter of Examples 1-6 includes, wherein a gate terminal of at least one NMOS transistor of the first set of NMOS transistors is coupled to a read wordline (RWL) terminal, and wherein a gate terminal of at least one PMOS transistor of the second set of PMOS transistors is coupled to a read wordline bar (RWLB) terminal.

In Example 8, the subject matter of Example 7 includes, wherein the corresponding set of source terminals of the first set of NMOS transistors are coupled to a first secondary local bitline (SLBL) terminal, and wherein the corresponding set of source terminals of the first set of PMOS transistors are coupled to a first primary local bitline (PLBL) terminal.

In Example 9, the subject matter of Example 8 includes wherein the corresponding set of source terminals of the second set of PMOS transistors are coupled to a second SLBL terminal and wherein the corresponding set of source terminals of the second set of NMOS transistors are coupled to a second PLBL terminal.

In Example 10, the subject matter of Examples 3-9 includes, a NOR gate, wherein an input terminal of the NOR gate is coupled to: the source terminal of the at least one PMOS transistor of the third set of PMOS transistors; and the corresponding set of source terminals of the second set of NMOS transistors.

In Example 11, the subject matter of Example 10 includes a coupling NMOS transistor and a delay circuit, wherein a source terminal of the coupling NMOS transistor is coupled to the GBL terminal, and a gate terminal of the coupling NMOS transistor is coupled to an output terminal of the NOR gate.

In Example 12, the subject matter of Examples 1-11 includes, wherein the memory circuit comprises a system-on-chip (SoC), the SoC comprising an integrated circuit (IC), the IC comprising at least two transistors of the first set of NMOS transistors, the second set of NMOS transistors, the first set of PMOS transistors, and the second set of PMOS transistors.

In Example 13, the subject matter of Example 12 includes, wherein the SoC further comprises at least one connector, and wherein the at least one connector conforms with at least one of Universal Serial Bus (USB), High-Definition Multimedia Interface (HDMI), Thunderbolt, Peripheral Component Interconnect Express (PCIe), and Ethernet specifications.

Example 14 is an apparatus comprising: an N-type bit-cell bundle, the N-type bit-cell bundle comprising: a first N-type bit-cell array; a first merge circuit; and a second N-type bit-cell array, the second N-type bit-cell array coupled to the first N-type bit-cell array via the first merge circuit; and a P-type bit-cell bundle coupled in a horizontal direction to the N-type bit-cell bundle via a spacer area, the P-type bit-cell bundle comprising: a first P-type bit-cell array; a second merge circuit; and a second P-type bit-cell array, the second P-type bit-cell array coupled to the first P-type bit-cell array via the second merge circuit.

In Example 15, the subject matter of Example 14 includes, a wordline driver slice, the wordline driver slice comprising a plurality of NOR gates coupled to a set of read wordline (RWL) terminals and a set of read wordline bar (RWLB) terminals.

In Example 16, the subject matter of Example 15 includes, wherein an output terminal of a first NOR gate of the plurality of NOR gates is coupled to at least one RWL terminal of the set of RWL terminals via a delay circuit, and wherein the at least one RWL terminal is coupled to the N-type bit-cell bundle.

In Example 17, the subject matter of Example 16 includes, wherein an output terminal of a second NOR gate of the plurality of NOR gates is coupled to at least one RWLB terminal of the set of RWLB terminals, and wherein the at least one RWLB terminal is coupled to the P-type bit-cell bundle.

In Example 18, the subject matter of Examples 14-17 includes, wherein the first P-type bit-cell array comprises: a first set of PMOS transistors comprising a corresponding set of source terminals, the first set of PMOS transistors coupled in parallel with each other via the corresponding set of source terminals of the first set of PMOS transistors.

In Example 19, the subject matter of Example 18 includes, wherein the second merge circuit comprises: a second set of PMOS transistors, wherein a drain terminal of at least one PMOS transistor of the second set of PMOS transistors is coupled to the corresponding set of source terminals of the first set of PMOS transistors; and a first set of NMOS transistors comprising a corresponding set of source terminals, the first set of NMOS transistors coupled in parallel with each other via the corresponding set of source terminals of the first set of NMOS transistors, wherein a gate terminal of at least one of the first set of NMOS transistors coupled to a global bitline (GBL) terminal, and wherein a source terminal of the at least one PMOS transistor of the second set of PMOS transistors is coupled to the corresponding set of source terminals of the first set of NMOS transistors.

Example 20 is a method for manufacturing a memory bit-cell array, the method comprising: coupling a first N-type bit-cell array and a second N-type bit-cell array via a first merge circuit to form an N-type bit-cell bundle; coupling a first P-type bit-cell array and a second P-type bit-cell array via a second merge circuit to form a P-type bit-cell bundle; coupling the P-type bit-cell bundle to the N-type bit-cell bundle via a spacer area; and coupling the P-type bit-cell bundle and the N-type bit-cell bundle to a wordline (WL) driver slice and a global bitline (GBL) terminal.

Example 21 is at least one machine-readable medium including instructions that, when executed by processing circuitry, cause the processing circuitry to perform operations to implement any of Examples 1-20.

Example 22 is an apparatus comprising means to implement any of Examples 1-20.

Example 23 is a system to implement any of Examples 1-20.

Example 24 is a method to implement any of Examples 1-20.

The above description is intended to be illustrative and not restrictive. For example, the above-described examples (or one or more aspects thereof) may be used in combination with others. Other embodiments may be used, such as by one of ordinary skill in the art upon reviewing the above description. The abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. A memory circuit comprising:
a first set of NMOS transistors comprising a corresponding set of source terminals, the first set of NMOS transistors coupled in parallel with each other via the corresponding set of source terminals of the first set of NMOS transistors;
a first set of PMOS transistors comprising a corresponding set of source terminals, the first set of PMOS transistors coupled in parallel with each other via the corresponding set of source terminals of the first set of PMOS transistors, and a gate terminal of at least one of the first set of PMOS transistors coupled to a global bitline (GBL) terminal;
a second set of PMOS transistors comprising a corresponding set of source terminals, the second set of PMOS transistors coupled in parallel with each other via the corresponding set of source terminals of the second set of PMOS transistors; and
a second set of NMOS transistors comprising a corresponding set of source terminals, the second set of NMOS transistors coupled in parallel with each other via the corresponding set of source terminals of the second set of NMOS transistors, and a gate terminal of at least one of the second set of NMOS transistors coupled to the GBL terminal.

2. The memory circuit of claim 1, further comprising:
a third set of NMOS transistors, wherein a drain terminal of at least one NMOS transistor of the third set of NMOS transistors is coupled to the corresponding set of source terminals of the first set of NMOS transistors, and wherein a source terminal of the at least one NMOS transistor of the third set of NMOS transistors is coupled to the corresponding set of source terminals of the first set of PMOS transistors.

3. The memory circuit of claim 2, further comprising:
a third set of PMOS transistors, wherein a drain terminal of at least one PMOS transistor of the third set of PMOS transistors is coupled to the corresponding set of source terminals of the second set of PMOS transistors, and wherein a source terminal of the at least one PMOS transistor of the third set of PMOS transistors is coupled to the corresponding set of source terminals of the second set of NMOS transistors.

4. The memory circuit of claim 2, wherein source terminals of the third set of NMOS transistors are coupled to a primary local bitline (PLBL) terminal.

5. The memory circuit of claim 4, further comprising:
a NAND gate, wherein an input terminal of the NAND gate is coupled to the PLBL and the corresponding set of source terminals of the first set of PMOS transistors.

6. The memory circuit of claim 5, further comprising:
a coupling NMOS transistor, wherein a source terminal of the coupling NMOS transistor is coupled to the GBL terminal, a gate terminal of the coupling NMOS transistor is coupled to a gate terminal of at least one PMOS transistor of the first set of PMOS transistors and an output terminal of the NAND gate.

7. The memory circuit of claim 1, wherein a gate terminal of at least one NMOS transistor of the first set of NMOS transistors is coupled to a read wordline (RWL) terminal, and wherein a gate terminal of at least one PMOS transistor of the second set of PMOS transistors is coupled to a read wordline bar (RWLB) terminal.

8. The memory circuit of claim 7, wherein the corresponding set of source terminals of the first set of NMOS transistors are coupled to a first secondary local bitline (SLBL) terminal, and wherein the corresponding set of source terminals of the first set of PMOS transistors are coupled to a first primary local bitline (PLBL) terminal.

9. The memory circuit of claim 8, wherein the corresponding set of source terminals of the second set of PMOS transistors are coupled to a second SLBL terminal, and wherein the corresponding set of source terminals of the second set of NMOS transistors are coupled to a second PLBL terminal.

10. The memory circuit of claim 3, further comprising:
a NOR gate, wherein an input terminal of the NOR gate is coupled to:
the source terminal of the at least one PMOS transistor of the third set of PMOS transistors; and
the corresponding set of source terminals of the second set of NMOS transistors.

11. The memory circuit of claim 10, further comprising:
a coupling NMOS transistor; and
a delay circuit, wherein a source terminal of the coupling NMOS transistor is coupled to the GBL terminal, and a gate terminal of the coupling NMOS transistor is coupled to an output terminal of the NOR gate.

12. The memory circuit of claim 1, wherein the memory circuit comprises a system-on-chip (SoC), the SoC comprising an integrated circuit (IC), the IC comprising at least two transistors of the first set of NMOS transistors, the second set of NMOS transistors, the first set of PMOS transistors, and the second set of PMOS transistors.

13. The memory circuit of claim 12, wherein the SoC further comprises at least one connector, and wherein the at least one connector conforms with at least one of Universal Serial Bus (USB), High-Definition Multimedia Interface (HDMI), Thunderbolt, Peripheral Component Interconnect Express (PCIe), and Ethernet specifications.

14. An apparatus comprising:
an N-type bit-cell bundle, the N-type bit-cell bundle comprising:
a first N-type bit-cell array;
a first merge circuit; and
a second N-type bit-cell array, the second N-type bit-cell array coupled to the first N-type bit-cell array via the first merge circuit; and
a P-type bit-cell bundle coupled in a horizontal direction to the N-type bit-cell bundle via a spacer area, the P-type bit-cell bundle comprising:
a first P-type bit-cell array;
a second merge circuit; and
a second P-type bit-cell array, the second P-type bit-cell array coupled to the first P-type bit-cell array via the second merge circuit.

15. The apparatus of claim 14, further comprising:
a wordline driver slice, the wordline driver slice comprising a plurality of NOR gates coupled to a set of read wordline (RWL) terminals and a set of read wordline bar (RWLB) terminals.

16. The apparatus of claim 15, wherein an output terminal of a first NOR gate of the plurality of NOR gates is coupled to at least one RWL terminal of the set of RWL terminals via a delay circuit, and wherein the at least one RWL terminal is coupled to the N-type bit-cell bundle.

17. The apparatus of claim 16, wherein an output terminal of a second NOR gate of the plurality of NOR gates is coupled to at least one RWLB terminal of the set of RWLB terminals, and wherein the at least one RWLB terminal is coupled to the P-type bit-cell bundle.

18. The apparatus of claim 14, wherein the first P-type bit-cell array comprises:
a first set of PMOS transistors comprising a corresponding set of source terminals, the first set of PMOS transistors coupled in parallel with each other via the corresponding set of source terminals of the first set of PMOS transistors.

19. The apparatus of claim 18, wherein the second merge circuit comprises:
a second set of PMOS transistors, wherein a drain terminal of at least one PMOS transistor of the second set of PMOS transistors is coupled to the corresponding set of source terminals of the first set of PMOS transistors; and
a first set of NMOS transistors comprising a corresponding set of source terminals, the first set of NMOS transistors coupled in parallel with each other via the corresponding set of source terminals of the first set of NMOS transistors,
wherein a gate terminal of at least one of the first set of NMOS transistors coupled to a global bitline (GBL) terminal, and
wherein a source terminal of the at least one PMOS transistor of the second set of PMOS transistors is coupled to the corresponding set of source terminals of the first set of NMOS transistors.

20. A process of making a memory bit-cell array, comprising:
coupling a first N-type bit-cell array and a second N-type bit-cell array via a first merge circuit to form an N-type bit-cell bundle;
coupling a first P-type bit-cell array and a second P-type bit-cell array via a second merge circuit to form a P-type bit-cell bundle;
coupling the P-type bit-cell bundle to the N-type bit-cell bundle via a spacer area; and
coupling the P-type bit-cell bundle and the N-type bit-cell bundle to a wordline (WL) driver slice and a global bitline (GBL) terminal.
